(19) United States
(12) Patent Application Publication
(10) Pub. No.: US 2025/0268071 A1
(43) Pub. Date: Aug. 21, 2025

(54) DISPLAY DEVICE

(71) Applicant: LG Display Co., Ltd., Seoul (KR)

(72) Inventor: Hyein PARK, Gwangju (KR)

(73) Assignee: LG Display Co., Ltd., Seoul (KR)

(21) Appl. No.: 19/019,149

(22) Filed: Jan. 13, 2025

(30) Foreign Application Priority Data
Feb. 20, 2024 (KR) 10-2024-0024157

(51) Int. Cl. H10K 59/80

(52) U.S. Cl. CPC H10K 59/873

(57) ABSTRACT

A display device in one example can include a base substrate including a display area and a non-display area, a bonding film and an encapsulation substrate disposed on the base substrate, and a dam disposed in the non-display area between the base substrate and the encapsulation substrate. The dam includes a first dam having a first spacer, and a second dam disposed between the bonding film and the first dam. The second dam has a second spacer that is softer than the first spacer.

### CROSS-REFERENCE TO RELATED APPLICATIONS

This application claims priority to Korean Patent Application No. 10-2024-0024157 filed on Feb. 20, 2024, in the Korean Intellectual Property Office, the entire contents of which is hereby expressly incorporated by reference into the present application.

### BACKGROUND

### Field

The present disclosure relates to a display device, and more particularly, to a display device with improved reliability.

### Discussion of the Related Art

Recently, display devices, which visually display electrical information signals, are being rapidly developed in accordance with the full-fledged entry into the information era. Various studies are being continuously conducted to develop a variety of display devices which are thin and lightweight, consume low power, and have improved performance.

As the representative display devices, there are a liquid crystal display device (LCD), an electrowetting display device (EWD), an organic light-emitting display device (OLED), a micro OLED device, and the like.

Among the display devices, an organic light-emitting display device can be known as a display device that autonomously emits light. Unlike a liquid crystal display apparatus, the organic light-emitting display device does not require a separate light source such as a backlight unit. Thus, the organic light-emitting display device can be manufactured as a lightweight, thin display device.

In addition, the organic light-emitting display device is advantageous in terms of power consumption since the electroluminescent display device operates at a low voltage.

Further, the organic light-emitting display device is expected to be adopted in various fields because the organic light-emitting display device is also excellent in implementation of colors, response speeds, viewing angles, and contrast ratios (CRs).

The organic light-emitting display device is configured such that a light-emitting layer made of an organic material is disposed between two electrodes being an anode and a cathode. When positive holes are injected into such organic light-emitting layer from the anode while electrons are injected into the same organic light-emitting layer from the cathode, the injected electrons and positive holes are recombined and produce excitons in the organic light-emitting layer.

The characteristics of the organic compounds/materials of the organic light-emitting element, however, can be degraded in case that the organic compounds are exposed to moisture. Therefore, there is a need to suppress any introduction of moisture into the pixels of the organic light-emitting display device.

### SUMMARY OF THE DISCLOSURE

An encapsulation technology for sealing an organic light-emitting element from an external environment is used for an organic light-emitting display device to suppress a degradation of the organic light-emitting element which may be caused by a penetration of moisture and oxygen into the pixels of the organic light-emitting display device. In that case, if a constant gap between an encapsulation substrate and a substrate of the organic light-emitting display device is not maintained during a process of joining the encapsulation substrate and the substrate, a defect can occur on the display device during the joining process.

Therefore, an object to be achieved by aspects of the present disclosure is to provide a display device having two or more types of dams to maintain a constant gap between an encapsulation substrate and a substrate.

Another object to be achieved by aspects of the present disclosure is to provide an organic light-emitting display device with an improved configuration, which enhances the reliability of the organic light-emitting display device and lengthens the lifespan of the organic light-emitting display device.

Another object to be achieved by aspects of the present disclosure is to provide an organic light-emitting display device, which addresses the limitations and disadvantages associated with the related art.

Objects of the present disclosure are not limited to the above-mentioned objects, and other objects, which are not mentioned above, can be clearly understood by those skilled in the art from the following descriptions.

In order to achieve the above-mentioned and other objects, a display device according to an embodiment of the present disclosure can include a substrate divided into a display area and a non-display area, a bonding film and an encapsulation substrate disposed on the substrate, and a dam disposed in the non-display area between the substrate and the encapsulation substrate, in which the dam includes a first dam having a first spacer, and a second dam disposed between the bonding film and the first dam and having a second spacer that is softer than the first spacer.

Other detailed matters of the example embodiments of the present disclosure are included in the detailed description and the drawings.

According to aspects of the present disclosure, the second dam is additionally disposed between the first dam and the bonding film, which can maintain a constant gap between the encapsulation substrate and the substrate. Therefore, it is possible to suppress or eliminate an external appearance limitation and non-cured limitation which can be caused by a dark spot.

According to aspects of the present disclosure, the spacer, which is softer than the spacer in the first dam, is applied to the second dam and is configured to be transformed in response to the joining process, which can inhibit or prevent the protective layer from cracking during the joining process. This provides an added protection and advantage to the display device of the present disclosure.

The effects and advantages according to aspects of the present disclosure are not limited to the contents provided in the present application, and more various effects and advantages are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a top plan view of a display device according to one or more embodiments of the present disclosure;

FIG. 2 is a cross-sectional view of a subpixel of the display device in FIG. 1 according to an example of the present disclosure;

FIG. 3 is a cross-sectional view taken along line I-I′ in FIG. 1 according to an example of the present disclosure;

FIG. 4 is a cross-sectional view taken along line II-II′ in FIG. 1 according to an example of the present disclosure;

FIG. 5 is a cross-sectional view taken along line III-III′ in FIG. 1 according to an example of the present disclosure;

FIG. 6 is an enlarged view of a part of a first dam in FIG. 3 according to an example of the present disclosure; and

FIG. 7 is an enlarged view of a part of a second dam in FIG. 3 according to an example of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure.

Further, in the following description of the present disclosure, a detailed explanation of known related technologies can be omitted to avoid unnecessarily obscuring the subject matter of the present disclosure. The terms such as “comprising,” “including,” “having,” “consist of,” etc. used herein are generally intended to allow other components to be added unless the terms are used with the term “only”. Any references to singular can include plural unless expressly stated otherwise.

Further, the term “can” fully encompasses all the meanings and coverages of the term “may.”

Components are interpreted to include an ordinary error range even if not expressly stated.

When the position relation between two parts is described using the terms such as “on”, “over,” “above”, “below”, “under”, “below,” “next”, etc., one or more parts can be positioned between the two parts unless the terms are used with the term “immediately” or “directly”.

When an element or layer is disposed “on,” “over,” or “above” another element or layer, another layer or other layers or elements can be interposed directly on the other element or therebetween.

Although the terms “first”, “second”, and the like are used for describing various components, these components are not confined by these terms. These terms are merely used for distinguishing one component from the other components, and may not define order or sequence. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other. For instance, any feature discussed herein in connection with any embodiment or example may be applied to any display device discussed herein in connection with any other embodiment or example.

Hereinafter, a display device according to various example embodiments of the present disclosure will be described in detail with reference to accompanying drawings. All the components of each display device according to all embodiments of the present disclosure are operatively coupled and configured.

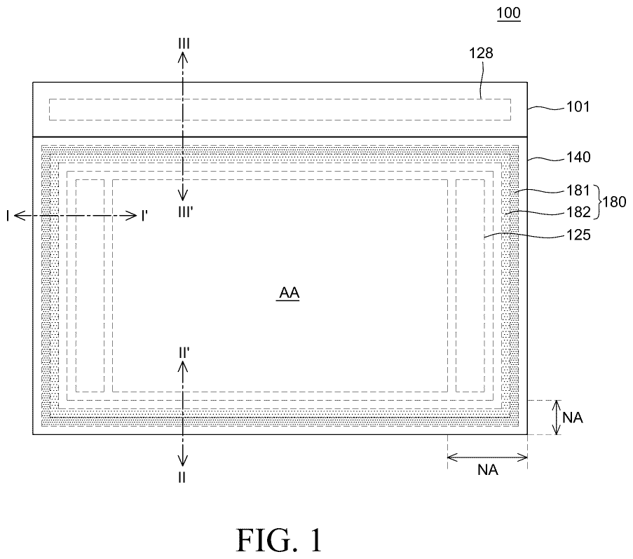

FIG. 1 is a top plan view of a display device according to an embodiment of the present disclosure.

With reference to FIG. 1, a display device 100 of an embodiment of the present disclosure can include a substrate 101, an encapsulation substrate 140, pad parts 125 and 128, and a dam 180. The substrate 101 and the encapsulation substrate 140 can be referred to as a first substrate and a second substrate, respectively, or can be referred to as a base substrate and an encapsulation substrate, respectively.

The display device 100 is a device configured to display images to a user.

The display device 100 can include a display element configured to display images, a driving element configured to operate the display element, and lines configured to transmit various types of signals to the display element and the driving element. Different display elements can be defined depending on the types of display devices 100. For example, in case that the display device 100 is an organic light-emitting display device, the display element can be an organic light-emitting element including an anode, an organic light-emitting layer, and a cathode. In another example, in case that the display device 100 is a liquid crystal display device, the display element can be a liquid crystal display element.

Hereinafter, it is assumed that the display device 100 and other display devices discussed below is an organic light-emitting display device including organic light-emitting elements. However, the display device 100 and other display devices are not limited to the organic light-emitting display device and can be of different types.

The display device 100 can be a transparent display device, e.g., transparent and/or flexible organic light-emitting display device. However, the present disclosure is not limited thereto.

The display device 100 can include a display area AA (or active area) and a non-display area NA (or non-active area).

The display area AA is an area of the display device 100 in which images are displayed.

The display area AA can include a plurality of subpixels configured to constitute a plurality of pixels, and one or more circuits configured to operate the plurality of subpixels. The plurality of subpixels are minimum units that constitute the display area AA.

The display element mentioned above can be disposed in each of the plurality of subpixels. The plurality (or group) of subpixels can constitute each pixel. For example, each of the plurality of subpixels can include the light-emitting element (e.g., organic light-emitting element) including an anode, a light-emitting layer (e.g., organic light-emitting layer having organic compound(s)/material(s)), and a cathode. However, the present disclosure is not limited thereto.

In addition, the circuit(s) configured to operate the plurality of subpixels can include driving elements, lines, and the like. For example, such circuit can include a thin-film transistor, a storage capacitor, a gate line, a data line, and the like. However, the present disclosure is not limited thereto.

The non-display area NA included in the display device 100 is an area in which no image is displayed.

The non-display area NA can surround entirely the display area AA having a quadrangular shape. However, the shapes and arrangements of the display area AA, the non-display area NA and the display device 100 are not limited to the example illustrated in FIG. 1.

In other words, the shape and/or arrangement of the display area AA and the non-display area NA can be suitable set for a design of an electronic device equipped with the display device 100. For example, another example shape of the display area AA can also be a pentagonal shape, a hexagonal shape, a circular shape, an elliptical shape, or the like.

Various lines and circuits for operating the organic light-emitting element in the display area AA can be disposed in the non-display area NA. For example, the non-display area NA can include link lines for transmitting signals to the plurality of subpixels and the circuits in the display area AA. The non-display area NA can include a drive IC such as a gate driver IC and a data driver integrated circuit (IC) and include the pad parts 125 and 128 (e.g., connected to the gate and data drivers) and the like. However, the present disclosure is not limited thereto.

The gate driver IC (or gate driver) can generate and provide gate signals to the pixels of the display device 100, and the data driver IC (or data driver) can generate and provide data signals to the pixels of the display device 100.

The display device 100 can include various additional elements configured to generate various signals or operate the pixel in the display area AA. The additional elements for operating the pixel(s) can include an inverter circuit, a multiplexer, an electrostatic discharge (ESD) circuit, and the like.

For example, the display device can include a timing controller, a power supply, etc. in addition to the gate driver and the data driver for driving the display device 100. The timing controller can receive image signals and control signals from an external host system or the like. The image signals can include a plurality of grayscale data. The control signals can include, for example, a vertical synchronization signal, a horizontal synchronization signal, a data enable signal, and the like.

The display device 100 can also include additional elements related to additional functions other than the function of operating the pixel. For example, the display device 100 can include additional elements that provide a touch detection function, a user certification function (e.g., fingerprint recognition), a multi-level pressure detection function, a tactile feedback function, and the like. The above-mentioned additional elements can be positioned in the non-display area NA, and/or the display area AA, and/or an external circuit connected to a connection interface.

The display device according to aspects of the present disclosure can be included in or applied to other electronic devices such as a TV, a mobile terminal such as a smart phone, a navigation system, a computer, a gaming system, an extended reality (XR) system, etc.

The pad parts 125 and 128 can be disposed to receive signals from the outside.

The pad parts 125 and 128 can be disposed in the non-display area NA of the display device 100 and electrically connected to a printed circuit board and various lines and circuits disposed in the display area AA.

For example, the pad parts 125 and 128 can serve to transmit signals to the gate lines and the data lines that are disposed to cross in the display area AA.

The pad parts 125 and 128 can include a gate pad part 125 configured to transmit gate signals to the gate lines, and a data pad part 128 configured to transmit data signals to the data lines. However, the present disclosure is not limited thereto.

The data pad part 128 can be disposed at one side of the display device 100, e.g., disposed in a first side of the non-display area NA of the display device 100. Here, the first side of the non-display area NA can be an upper/top side of the display device 100. However, the present disclosure is not limited thereto, and the first side can be a lower/bottom side of the display device 100.

The gate pad part 125 can be disposed at one or more sides of the display device 100, e.g., disposed in a third side of the non-display area NA of the display device 100. For example, the third side can be a lateral portion of the display device 100 adjacent to the upper and lower sides, such as left and right sides of the display device 100 in FIG. 1. However, the present disclosure is not limited thereto.

In an example, the data pad part 128 can be electrically connected to the data driver and supply data voltages to the plurality of data lines. The data driver can receive image data from the timing controller and supply data voltages to the plurality of data lines to operate the plurality of data lines. The data driver can be implemented by including one or more source driver integrated circuits. The data driver can be disposed to overlap with or be adjacent to the data pad part 128. For instance, the data driver can be disposed be directly on or below the data pad part 128.

As an example, the source driver integrated circuits can each include a shift register, a latch circuit, a digital-analog converter (DAC), an output buffer, and the like. In some instances, the data driver can further include one or more analog-digital converters (ADC).

Meanwhile, the gate driver can operate the plurality of gate lines by outputting scan signals to the plurality of gate lines. For example, the gate driver can sequentially operate the plurality of gate lines by sequentially supplying scan signals to the plurality of gate lines. The gate driver can sequentially supply the scan signals with ON-voltages or OFF-voltages to the plurality of gate lines under the control of the timing controller.

The gate driver can include a plurality of gate drive circuits. In this case, the plurality of gate drive circuits can respectively correspond to the plurality of gate lines.

For example, the gate drive circuits can each include a shift register, a level shifter, and the like.

The gate drive circuits can each be implemented as a gate-in-panel (GIP) type and embedded in the display device 100. For example, the gate drive circuits can each be disposed directly on or below the gate pad part 125, or can each be disposed to overlap with or be adjacent to the gate pad part 125. In the example of FIG. 1, the gate driving circuit(s) can be disposed on one or more gate pad parts 125 disposed on the two opposite sides of the display device 100.

Meanwhile, the display device 100 according to the embodiment of the present disclosure can include the dam 180 provided in the non-display area NA to ensure the reliability while suppressing moisture penetration.

The dam 180 can be disposed in a shape that surrounds the display area AA.

For example, the dam 180 can be disposed in a quadrangular frame shape that surrounds the display area AA entirely. Four edges of the dam 180 can each have a predetermined curvature.

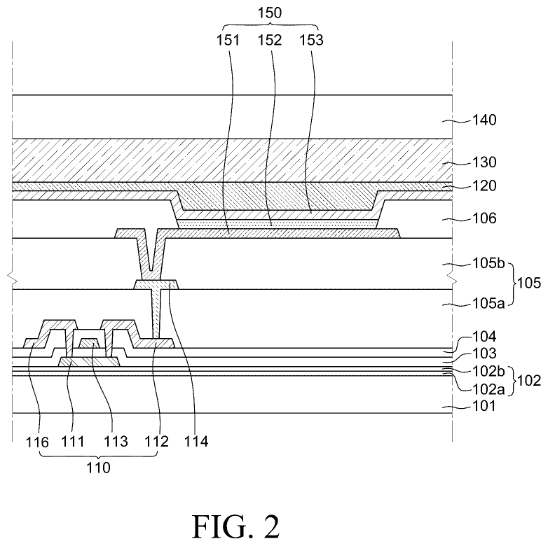

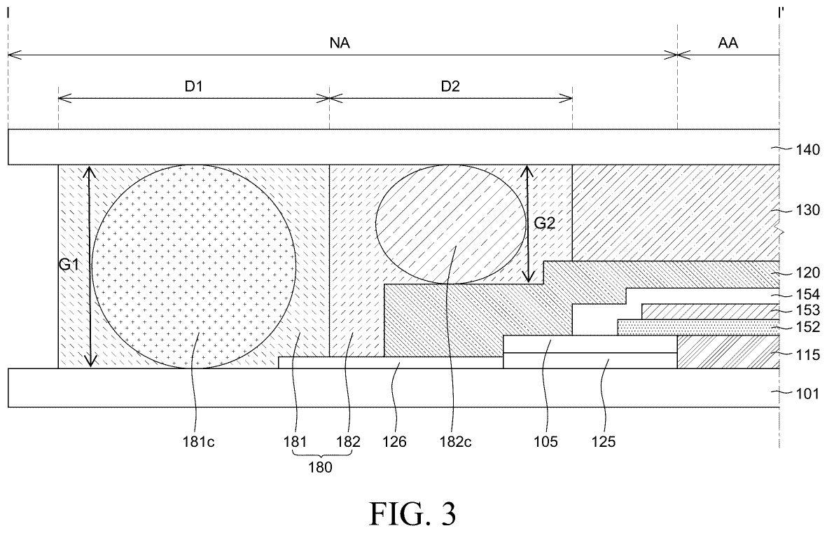

In addition, in the display device 100 of the embodiment of the present disclosure, the dam 180 can include a transparent getter and resin to implement a transparent display device. The dam 180 includes a first dam 181, but can further include a second dam 182 additionally disposed between the first dam 181 and a bonding film, such that a constant gap between the encapsulation substrate 140 and the substrate 101 can be maintained. This configuration will be described now in more detail with reference to FIGS. 3 to 7 along with FIG. 2 according to examples of the present disclosure.

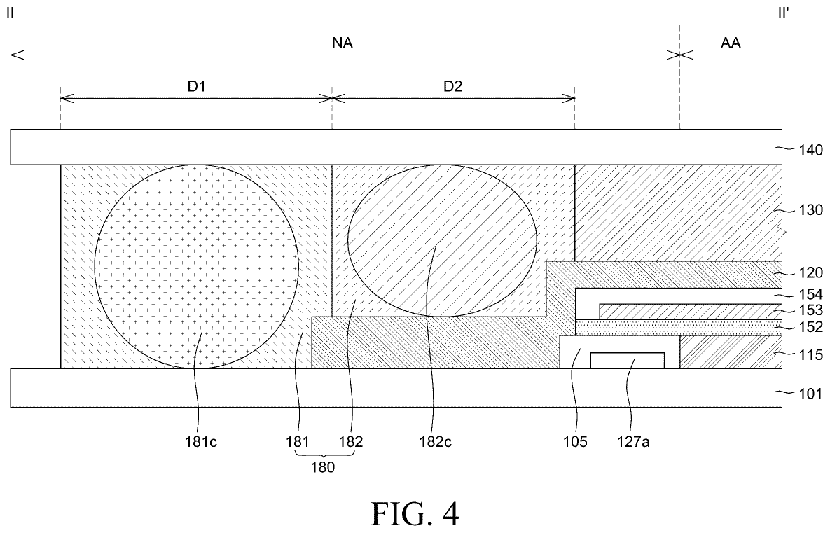

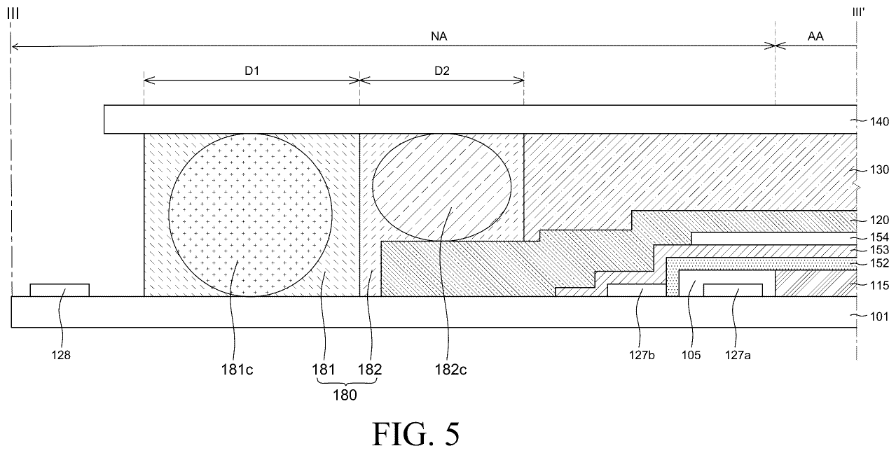

Specifically, FIG. 2 is a cross-sectional view of a subpixel of the display device in FIG. 1. Each subpixel of the display device 100 in this and other embodiments can have the configuration of the subpixel shown in FIG. 2, but can have other configurations. FIG. 3 is a cross-sectional view taken along line I-I′in FIG. 1. FIG. 4 is a cross-sectional view taken along line II-Il′in FIG. 1. FIG. 5 is a cross-sectional view taken along line III-III′ in FIG. 1.

For convenience of description, FIGS. 3 to 5 schematically illustrate a pixel part 115 in the display area AA. The pixel part 115 can include various types of components disposed below a planarization layer 105. In addition, for convenience of description, FIGS. 3 and 5 schematically illustrate the gate pad part 125 and the data pad part 128 in the non-display area NA. The gate pad part 125 can include various types of components including a GIP circuit part.

Particularly, FIG. 3 illustrates a part of a left non-display area NA and an adjacent part of the display area AA of the display device 100 in FIG. 1. In addition, FIG. 4 illustrates a part of a second side non-display area NA and an adjacent part of the display area AA of the display device 100 in FIG. 1. In addition, FIG. 5 illustrates a part of the first side non-display area NA and an adjacent part of the display area AA of the display device 100 in FIG. 1. In this example, the first side can be the upper side of the display device 100 illustrated in FIG. 1, and the second side can be the lower side positioned opposite to the upper side. However, other variations are possible. For instance, the first and second sides can be opposite sides or directly adjacent sides (e.g., sides forming 90 degrees or other degrees).

With reference to FIGS. 2 to 5, in the display device (100 in FIG. 1) of the embodiment of the present disclosure, a driving element 110 can be disposed on the substrate 101.

Further, the planarization layer 105 can be disposed on the driving element 110.

In addition, an organic light-emitting element 150, which is electrically connected to the

driving element 110, can be disposed on the planarization layer 105, and a protective layer 120 can be disposed on the organic light-emitting element 150, thereby suppressing any penetration of oxygen and moisture into the organic light-emitting element 150.

A bonding film 130 and the encapsulation substrate 140 can be sequentially disposed on the protective layer 120. However, the present disclosure is not limited to the above-mentioned stacked structure.

The substrate 101 can be a glass or plastic substrate. In case that the substrate is a plastic substrate, a polyimide-based material or a polycarbonate-based material is used, such that the substrate can have flexibility. In particular, polyimide is widely used for the plastic substrate because polyimide is a material that can be applied to a high-temperature process and used for coating. As such, the substrate 101 can be flexible (e.g., bendable, rollable, etc.).

A buffer layer 102 can be disposed on the substrate 101. The buffer layer 102 can be a layer for protecting various types of electrodes and lines from impurities such as alkaline ions leaking from the substrate 101 or lower layers. The buffer layer 102 can have a multilayer structure including a first buffer layer 102a and a second buffer layer 102b. However, the present disclosure is not limited thereto. For example, the buffer layer 102 can have a single-layer structure. Further, the buffer layer 102 can be made of silicon oxide (SiOx) or silicon nitride (SiNx) or configured as a multilayer including silicon oxide (SiOx) or silicon nitride (SiNx).

The buffer layer 102 can delay or protect the diffusion of moisture and/or oxygen that might have penetrated into the substrate 101. The buffer layer 102 can include a multi-buffer and/or an active buffer. The active buffer can serve to protect an active layer 111 of the driving element 110, and the active layer 111 can be made of a semiconductor. The active buffer can serve to block various types of elements which may be introduced from the substrate 101. The active buffer can be made of amorphous silicon (a-Si) or the like.

As a non-limiting example, the driving element 110 can be configured such that the active layer 111, an insulation layer 103, a gate electrode 113, a gate insulation layer 104, a source electrode 116, and a drain electrode 112 are sequentially disposed. The driving element 110 can be electrically connected to the organic light-emitting element 150 through a connection electrode 114 and transmit an electric current or signal from the driving element 110 to the organic light-emitting element 150. For instance, the driving element 110 can be a thin film transistor of various types, and depending on the type of the driving element 110, the locations of the source electrode 116 and the drain electrode 112 can be switched or varied.

The active layer 111 can be positioned on the buffer layer 102. The active layer 111 can be made of polysilicon (p-Si). In this case, a predetermined area of the active layer 111 can be doped with impurities. In addition, the active layer 111 can be made of amorphous silicon (a-Si) or an organic semiconductor material such as pentacene. In addition, the active layer 111 can be made of an oxide.

The insulation layer 103 can be positioned on the active layer 111. The insulation layer 103 can be made of an insulating inorganic material such as silicon oxide (SiOx) or silicon nitride (SiNx). In addition, the insulation layer 103 can be made of an insulating organic material or the like.

The gate electrode 113 can be positioned on the insulation layer 103. The gate electrode 113 can be made of various electrically conductive materials, for example, magnesium (Mg), aluminum (Al), nickel (Ni), chromium (Cr), molybdenum (Mo), tungsten (W), gold (Au), or an alloy thereof.

The gate insulation layer 104 can be positioned on the gate electrode 113. The gate insulation layer 104 can be made of an insulating material such as silicon oxide (SiOx) or silicon nitride (SiNx). In addition, the gate insulation layer 104 can be made of an insulating organic material.

In this case, contact holes, through which source and drain areas are exposed, can be formed by selectively removing portions of the insulation layer 103 and the gate insulation layer 104, where the source and drain electrodes 116, 112 can be disposed in such contact holes. The source electrode 116 and the drain electrode 112 can each have a single-layer or multilayer structure disposed on the gate insulation layer 104 and made of a material for an electrode. If necessary, an additional protective layer (e.g., passivation layer) made of an inorganic insulating material can be formed to cover the source electrode 116 and the drain electrode 112.

The planarization layer 105 can be disposed on the driving element 110 configured as described above.

The planarization layer 105 can have a multilayer structure including at least two layers. For example, the planarization layer 105 can include a first planarization layer 105a and a second planarization layer 105b. The first planarization layer 105a can be disposed to cover the driving element 110 while the drain electrode 112 of the driving element 110 is partially exposed.

The planarization layer 105 can extend into the non-display area NA of the display device 100.

The planarization layer 105 can be an overcoat layer. However, the present disclosure is not limited thereto.

In addition, the connection electrode 114 can be disposed on the first planarization layer 105a and electrically connect the driving element 110 to the organic light-emitting element 150. In addition, various metal layers can be disposed on the first planarization layer 105a and serve as electrodes and electric wires such as data lines or signal lines.

In addition, the second planarization layer 105b can be disposed on the first planarization layer 105a and the connection electrode 114. The configuration in which the planarization layer 105 of the embodiment of the present disclosure is provided as two layers is based on the fact that the number of various types of signal lines increases as the organic light-emitting display device has a high resolution. The additional layer can be provided since it may be difficult to dispose all the lines on a single layer while ensuring minimum intervals. The addition of the additional layer (e.g., the second planarization layer 105b) can provide a margin for disposing lines, which further facilitates the disposition design of lines/electrodes. Further, in case that a dielectric material is used for the planarization layer 105 having a multilayer structure, the planarization layer 105 can serve to create a capacitance between the metal layers.

The second planarization layer 105b can be formed such that a part of the connection electrode 114 is exposed through the second planarization layer 105b. As such, the drain electrode 112 of the driving element 110 and an anode 151 of the organic light-emitting element 150 can be electrically connected to each other by the connection electrode 114.

The organic light-emitting element 150 can be configured by sequentially disposing the anode 151, one or a plurality of organic layers 152, and a cathode 153. For example, the organic light-emitting element 150 can include the anode 151 formed on the planarization layer 105, the organic layer 152 formed on the anode 151, and the cathode 153 formed on the organic layer 152. The organic layer 152 is an organic light-emitting layer, but can be of a different type.

The organic light-emitting display device including the plurality of subpixels in all embodiments of the present disclosure can be implemented as a top emission type or a bottom emission type. In the case that the display device is of the top emission type, a reflective layer made of an opaque conductive material with high reflectance, for example, silver (Ag), aluminum (Al), gold (Au), molybdenum (Mo), tungsten (W), chromium (Cr), or an alloy thereof can be additionally disposed on a lower portion of the anode 151 so that light, which is emitted from the organic layer 152, is reflected by the anode 151 and propagates upward, e.g., in a direction toward the cathode 153 at the upper side of the display device. In contrast, in the case that the display device is of the bottom emission type, the anode 151 can be made of only a transparent electrically conductive material such as indium tin oxide (ITO), indium zinc oxide (IZO), or indium gallium zinc oxide (IGZO). Hereinafter, the description will be made on the assumption that the organic light-emitting display device in the examples of the present disclosure is the top emission type, but the concepts and advantageous features of the present invention are equally applicable to other types of display devices.

A bank 106 can be provided on the planarization layer 105 and formed in the remaining area excluding the light-emitting area. For example, the bank 106 has a bank hole through which the anode 151 corresponding to the light-emitting area is exposed. The bank 106 can be made of an inorganic insulating material such as silicon nitride (SiNx) or silicon oxide (SiOx) or made of an organic insulating material such as BCB, acrylic resin, or imide-based resin.

The bank 106 can extend into the non-display area NA of the display device 100.

The organic layer 152 of the organic light-emitting element 150 can be disposed on the anode 151 exposed by the bank 106. The organic layer 152 can include a light-emitting layer, an electron injection layer, an electron transport layer, a hole transport layer, a hole injection layer, and the like, but can have other structures/configurations.

The organic layer 152 can extend into the non-display area NA of the display device 100.

In the non-display area NA, the organic layer 152 can be disposed on the planarization layer 105. The cathode 153 of the organic light-emitting element 150 can be disposed on the organic layer 152.

In the case of the top emission type, the cathode 153 can include a transparent electrically conductive material. For example, the cathode 153 can be made of indium tin oxide (ITO), indium zinc oxide (IZO), indium gallium zinc oxide (IGZO), or the like. In the case of the bottom emission type, the cathode 153 can include any one selected from a group consisting of metallic materials such as gold (Au), silver (Ag), aluminum (Al), molybdenum (Mo), magnesium (Mg), palladium (Pd), and copper (Cu) or an alloy thereof. Alternatively, the cathode 153 can be configured by stacking a layer made of a transparent electrically conductive material such as indium tin oxide (ITO), indium zinc oxide (IZO), or indium gallium zinc oxide (IGZO) and a layer made of metallic materials such as gold (Au), silver (Ag) aluminum (Al), molybdenum (Mo), magnesium (Mg), palladium (Pd), and copper (Cu) or an alloy thereof. However, the present disclosure is not limited thereto.

The cathode 153 can extend into the non-display area NA.

The protective layer 120 can be disposed on the cathode 153 and cover the planarization layer 105 and the cathode 153.

A capping layer 154 can be disposed on the cathode 153. The capping layer 154 can be made of a material with a large refractive index and a high optical absorption rate to reduce an irregular reflection of external light.

The protective layer 120 can be an inorganic layer. In this case, the protective layer 120 can be made of silicon oxide (SiOx) or silicon nitride (SiNx) or configured as a multilayer including silicon oxide (SiOx) or silicon nitride (SiNx).

The protective layer 120 can extend into the non-display area NA.

The protective layer 120 can be disposed to cover the cathode 153 and the planarization layer 105.

The bonding film 130 and the encapsulation substrate 140 can be disposed on the protective layer 120.

The bonding film 130 can be disposed to surround the protective layer 120, e.g., in part.

The bonding film 130, together with the protective layer 120 and the encapsulation substrate 140, can protect the organic light-emitting element 150 of the pixel part 115 from outside moisture, oxygen, impact, and the like. The bonding film 130 can further include a moisture absorbent material. The moisture absorbent material can include particles having hygroscopicity. The moisture absorbent material can absorb moisture, oxygen, and the like from the outside, thereby minimizing a degree to which moisture and oxygen penetrate into the pixel part 115. However, the present disclosure is not limited thereto.

The bonding film 130 can include a moisture absorbent (filler). For example, the moisture absorbent (filler) can be made of a transparent material so that brightness does not deteriorate while light emitted from the organic light-emitting element 150 passes through the encapsulation substrate 140. For example, the moisture absorbent material can be made of epoxy or olefin and include talc, calcium oxide (CaO), barium oxide (BaO), zeolite (zeolite), silicon oxide (SiO), and the like.

The encapsulation substrate 140 can be disposed on the bonding film 130. The encapsulation substrate 140, together with the bonding film 130, can protect the organic light-emitting element 150 of the pixel part 115. The encapsulation substrate 140 can protect the organic light-emitting element 150 from outside moisture, oxygen, impact, and the like.

With reference to FIG. 3, the gate pad part 125 can be disposed at a side of the pixel part 115 in the left (and/or right) non-display area NA. The gate pad part 125 can include various types of components including the GIP circuit part.

The planarization layer 105 can be disposed above the gate pad part 125 and extend. The edges of the planarization layer 105 and the gate pad part 125 can be aligned, where the planarization layer 105 and the gate pad part 125 can extend from the pixel part 115.

The organic layer 152 can be disposed to extend to cover a part of the planarization layer 105 disposed above the gate pad part 125. In addition, the capping layer 154 can be disposed to extend to cover another part of the planarization layer 105 disposed above the gate pad part 125.

A GIP line 126 can be disposed toward the outside of the substrate 101 from the gate pad part 125. However, the present disclosure is not limited thereto. In this example, the GIP line 126 is disposed adjacent to the gate pad part 125 in the non-display area NA.

The protective layer 120 can be disposed to extend to partially cover the planarization layer 105, the capping layer 154, and the GIP line 126.

With reference to FIG. 4, a pixel power shorting bar 127a can be disposed at the side of the pixel part 115 in the second side (lower side) non-display area NA of the display device 100. However, the present disclosure is not limited thereto. The pixel power shorting bar 127a can be connected to a plurality of pixel power lines provided in the display area AA. The pixel power shorting bar 127a can be a first power shorting bar, for instance. The pixel power shorting bar 127a can be disposed in the non-display area NA and can be covered by the planarization layer 105 adjacent to the pixel part 115.

That is, the planarization layer 105 can be disposed to extend to cover the pixel power shorting bar 127a.

The organic layer 152 can be disposed to extend to cover a part of the extending planarization layer 105. In addition, the cathode 153 can be disposed on the organic layer 152 and extend.

The capping layer 154 can be disposed to extend to cover the cathode 153. As an example, the end portions of the organic layer 152 and the capping layer 154 can be aligned to each other, and can be aligned with an end portion of the bonding film 130.

The protective layer 120 can be disposed to extend to cover the planarization layer 105 and the capping layer 154 as well as a portion of the substrate 101.

With reference to FIG. 5, the pixel power shorting bar 127a can be disposed on the side surface of the pixel part 115 in the first side (upper side) non-display area NA. However, the present disclosure is not limited thereto. The pixel power shorting bar 127a can be connected to the plurality of pixel power lines provided in the display area AA. The pixel power shorting bar 127a can be the first power shorting bar.

The planarization layer 105 can be disposed to extend to cover the pixel power shorting bar 127a as mentioned above.

The organic layer 152 can be disposed to extend to cover of the extending planarization layer 105 in the non-display area NA, and contacts a portion of the substrate 101.

In addition, a common power shorting bar 127b can be disposed at a side surface of the extending organic layer 152 in the non-display area NA. The common power shorting bar 127b can be connected to a plurality of common power lines provided in the display area AA. The common power shorting bar 127b can be a second power shorting bar.

In addition, the arrangement of the pixel power shorting bar 127a and the arrangement of the common power shorting bar 127b can be interchangeable. For instance, in another example, the pixel power shorting bar 127a can be located where the common power shorting bar 127b is located, and vice versa.

The cathode 153 can be disposed to extend to cover the common power shorting bar 127b and the organic layer 152, and can contact a portion of the substrate 101 in the non-display area NA. A part of the extending cathode 153 can constitute a common power line.

The capping layer 154 can be disposed on the cathode 153 and extend into the non-display area.

The protective layer 120 can be disposed to extend to cover the cathode 153 and the capping layer 154 as well as a portion of the substrate 101.

Now with reference back to FIGS. 1 to 5, the dam 180 can be provided at and along the edge or edge portion of the substrate 101 and disposed between the substrate 101 and the encapsulation substrate 140. The dam 180 can reinforce a bonding force between the substrate 101 and the encapsulation substrate 140 and block moisture.

The dam 180 can be disposed in the non-display area NA at the outer periphery of the display area AA. For example, the dam 180 is formed to surround the pixel part 115 in a plan view. The dam 180 can surround the entirely an area composed of the display area AA and the gate pad parts 125. The dam 180, together with the bonding film 130, can bond and seal the substrate 101 and the encapsulation substrate 140 to each other, e.g., in the non-display area NA.

The dam 180 can include the first dam 181 and the second dam 182. For example, the first dam 181 can be disposed at an edge (e.g., side edge) of the second dam 182. The second dam 182 can be disposed at the edge of the substrate 101, and the first dam 181 can be disposed outside the second dam 182. The second dam 182 and the first dam 181 can be sequentially disposed in an outward direction, and the substrate 101 and the encapsulation substrate 140 can be sealed by the formation of the bonding film 130, the second dam 182 and the first dam 181.

As an example, the bonding film 130 and the first and second dams 181 and 182 can fill completely an area above the protective layer 120 between the substrate 101 and the encapsulation substrate 140, so as to bond and seal the substrate 101 and the encapsulation substrate 140 to each other well. In a variation, the first and second dams 181 and 182 can be a single dam extending from the bonding film outwardly to cover an end/outer edge area of the substrate 101 in the non-display area NA of the display device 100.

In a plan view, the first dam 181 and the second dam 182 can have frame shapes provided around the display area AA to surround the display area AA entirely.

The first dam 181 can be disposed in a first area DI of the non-display area NA.

Here, a first gap (e.g., G1 in FIG. 3) can be formed between the substrate 101 and the encapsulation substrate 140 in the first area D1. For example, the encapsulation substrate 140, the first dam 181, and the substrate 101 can be included in the first area D1. The first dam 181 can maintain the first gap G1 and be disposed in the first area DI between the substrate 101 and the encapsulation substrate 140.

In the left non-display area NA (see FIG. 3), the GIP line 126 can partially extend into the first area D1. However, the present disclosure is not limited thereto.

In addition, in the second side (lower side) non-display area NA (see FIG. 4), the protective layer 120 can extend through a second area D2 of the non-display area NA and further partially extend into the first area DI of the non-display area NA. However, the present disclosure is not limited thereto.

Now referring back to FIGS. 3 to 5, the second dam 182 can be disposed in the second area D2.

A second gap (e.g., G2 in FIG. 3) can be formed between the encapsulation substrate 140 and the protective layer 120 in the second area D2. For example, the encapsulation substrate 140, the second dam 182, the protective layer 120, the substrate 101, and a part of the component extending into the non-display area NA can be included in the second area D2. In addition, a part of the second area D2 may not include the protective layer 120 while another part of the second area D2 can include the protective layer 120.

In the left non-display area NA (see FIG. 3), the planarization layer 105, the gate pad part 125, the GIP line 126, and the protective layer 120 can partially extend into the second area D2. However, the present disclosure is not limited thereto.

In the second side (lower side) non-display area NA (see FIG. 4), the planarization layer 105 and the protective layer 120 can partially extend into the second area D2. However, the present disclosure is not limited thereto.

In the first side (upper side) non-display area NA (see FIG. 5), the protective layer 120 can partially extend into the second area D2. However, the present disclosure is not limited thereto.

Referring to FIGS. 3 to 5, the second dam 182 can maintain the second gap and be disposed between the protective layer 120 and the encapsulation substrate 140 and/or between the encapsulation substrate 140 and the substrate 101. For example, the second dam 182 can be disposed between the protective layer 120 and the encapsulation substrate 140. For example, the second dam 182 can be disposed between the encapsulation substrate 140 and the substrate 101. For example, the second dam 182 can be disposed between the encapsulation substrate 140 and the substrate 101 and between the encapsulation substrate 140 and the protective layer 120 and/or between the encapsulation substrate 140 and the GIP line 126.

In case that only the first dam 181 is present without the second dam 182, a gap between the encapsulation substrate 140 and the substrate 101 can be narrowed (or smaller) because of a difference in fluidity between a sealant component and a spacer component of the first dam 181. The narrowed gap may cause limitations such as a dark spot issue or a separation issue. Therefore, the display device 100 according to the embodiment of the present disclosure can have both the first and second dams 181 and 182 (or their structures) to avoid such limitations.

More specifically, in a related art, a spacer can be included in a dam material to maintain a gap during a process of joining an encapsulation substrate and a substrate. In that case, since a sealant component in the dam has a higher fluidity than the spacer, the sealant component can be pushed toward an outer peripheral portion during the process of joining the encapsulation substrate and the substrate, so that the spacer for maintaining a gap is pushed out and is not present at a boundary between the dam and the bonding film. Due the gap at the boundary between the dam and the bonding film being narrowed as described above, a dark spot defect can occur as the outer peripheral portion is pushed out. In addition, since such a space can be formed by the difference in fluidity between the sealant and the spacer, a separation area can be formed, which can cause a defective external appearance. Further, in case that the spacer is positioned on a protective layer, the spacer can be pushed out or pressed by the narrowed gap, which can result in the protective layer being cracked. As such, a non-cured moisture absorbent element, out-gas, or the like can be introduced through the crack, which can cause a dark spot defect.

Therefore, to address these limitations associated with the related art, in the embodiments of the present disclosure, the second dam 182 is additionally disposed between the first dam 181 and the bonding film 130 to maintain (or help maintain) a constant gap between the encapsulation substrate 140 and the substrate 101.

In addition, in the embodiments of the present disclosure, a spacer 182c, which is softer than a spacer 181c in the first dam 181, is applied to the second dam 182 and configured to be transformed (e.g., pressed, flattened or deformed) in response to or during the joining process of the substrate 101 and the encapsulation substrate 140, which can prevent or inhibit the protective layer 120 from cracking during such joining process.

More specifically, referring to FIGS. 3 to 5, the first dam 181 can include the first spacer 181c. The second dam 182 can contain the second spacer 182c.

The first spacer 181c can be a hard spacer. The second spacer 182c can be a soft spacer. The first spacer 181c can have a higher hardness and/or higher recovery rate than the second spacer 182c.

For example, a recovery rate refers to the degree to which a spacer returns to its original shape due to its restorative force after pressure is applied and then removed. When pressure is applied, the spacer compresses by a distance of S, and when the pressure is released, it recovers by a distance of L due to its restorative force. The recovery rate is defined as (L/S)×100%.

The first spacer 181c can have a higher hardness than the second spacer 182c. For example, the first spacer 181c can have a 10% K value of about 4,400 N/mm², and the second spacer 182c can have a 10% K value of about 1,600 N/mm². The 10% K value can be a value corresponding to the lowest 10% of strength or hardness of a particular material.

In another example, the first spacer 181c can have a higher recovery rate than the second spacer 182c. For example, the first spacer 181c and the second spacer 182c can respectively have a recovery rate of about 52% and 7%.

In addition, for example, the first spacer 181c can have both a higher hardness and a higher recovery rate than the second spacer 182c.

Meanwhile, the second spacer 182c can be transformed (e.g., pressed, flattened, deformed, etc.) in an elliptical shape by a joining force applied by the encapsulation substrate 140 and the substrate 101. The second spacer 182c can be present in an elliptical shape in a state in which the encapsulation substrate 140 and the substrate 101 are pressed in to be joined to each other. In contrast, the first spacer 181c with a high hardness and/or restoring force can be present in more a circular shape. Because the second spacer 182c has a lower hardness and/or restoring force as described above (e.g., the second spacer 182c is softer than the first spacer 181c), the second spacer 182c disposed between the encapsulation substrate 140 and the protective layer 120 does not damage the protective layer 120. For instance, due to the softness of the second spacer 182c, during the bonding/joining of the substrate 101 and the encapsulation substrate 140, the second spacer 182 may be more flattened or deformed (e.g., from a circle to an elliptical shape), which does not press into and does not damage an upper portion of the protective layer 120 while maintaining the gap between the substrate 101 and the encapsulation substrate 140.

For example, the first spacer 181c can have a particle diameter of about 10 um. In addition, a minor axis of the second spacer 182c transformed (e.g., flattened, pressed, deformed, etc.) in an elliptical shape can have a smaller size than the particle diameter of the first spacer 181c. For example, a length of the minor axis of the second spacer 182c can be less or shorter than about 10 um that is the particle diameter of the first spacer 181c. However, the present disclosure is not limited thereto.

Further, as a variation, one or more first spacers 181c can be disposed vertically or substantially vertically in an area between the substrate 101 and the encapsulation substrate 140. In addition or in the alternative, one or more second spacers 182c can be disposed vertically or substantially vertically in an area between the substrate 101 and the encapsulation substrate 140.

For example, the first spacer 181c and the second spacer 182c initially having a circular shape according to aspects of the present disclosure can be identified by a scanning electron microscope (SEM) analysis. According to the result of evaluating a cross-section through the SEM analysis after joining/bonding the encapsulation substrate 140 and the substrate 101, the inventor was able to identify that the first spacer (e.g., 181c) was kept substantially circular, and the second spacer (e.g., 182c) was transformed (e.g., flattened, deformed, pressed, etc.) substantially in an elliptical shape.

As described above, the soft second spacer 182c is disposed in the second dam 182 being located between the first spacer 181c and the bonding film 130, which can compensate for a decrease in the gap between the first dam 181 and the bonding film 130. This compensation in the decrease of the gap can prevent or suppress a dark spot defect and a separation defect, effectively and advantageously. In addition, the use of the soft second spacer 182c can prevent or inhibit the protective layer 120 from cracking.

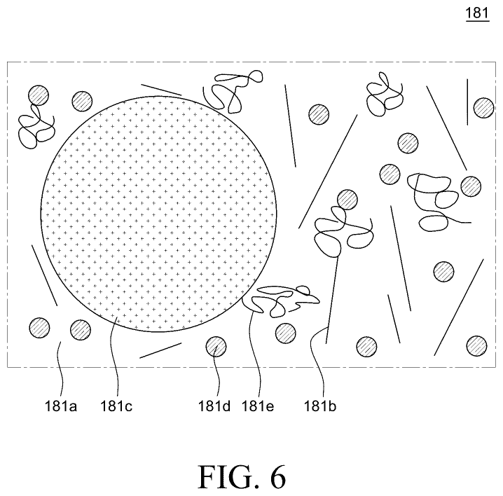

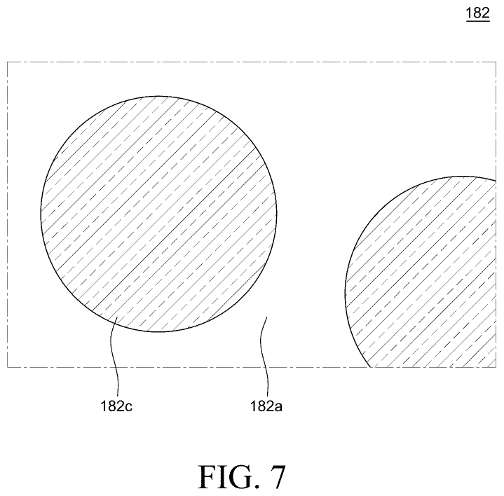

FIG. 6 is an enlarged view of a part of the first dam in FIG. 3 according an example of the present disclosure. FIG. 7 is an enlarged view of a part of the second dam in FIG. 3 according an example of the present disclosure.

Particularly, FIG. 6 relates to the first dam 181 and schematically illustrates materials that can constitute the first dam 181.

Referring to FIG. 6, the first dam 181 can be made of transparent materials to implement a transparent display device.

For example, the transparent materials, which can constitute the first dam 181, can include a first sealant 181a, a first moisture absorbent 181b (also referred to herein as a first moisture absorbent material or a first moisture absorbing element), and the first spacer 181c.

The transparent materials, which can constitute the first dam 181, can further include a first getter 181d. The transparent materials, which can constitute the first dam 181, can further include a first polymer light-emitting material 181e. According to the embodiment of the present disclosure, the first getter 181d and/or first polymer light-emitting material 181e can be selectively excluded.

The first dam 181 can include the first sealant 181a. The first sealant 181a can be a thermosetting or ultraviolet (UV) curable sealant. For example, the first sealant 181a can be selected as an epoxy-based or acrylic-based sealant with an added thermosetting promoter and/or photoinitiator. However, the present disclosure is not limited thereto. The first sealant 181a can be made of a transparent material to implement the transparent first dam 181. However, the present disclosure is not limited thereto. The first sealant 181a can reinforce a bonding force between the substrate 101 and the encapsulation substrate 140 by joining the substrate 101 and the edge of the encapsulation substrate 140.

The first dam 181 can include the first moisture absorbent material 181b. The first moisture absorbent material 181b can be dispersed in the first sealant 181a. The first moisture absorbent material 181b can be made of a material capable of absorbing moisture. The first moisture absorbent material 181b (or first moisture absorbing element) can be grinded into small sizes and uniformly dispersed in the first sealant 181a.

The first moisture absorbent material 181b is not limited to any particular material, but can be made of, for example, an alkali metal oxide, silica, porous zeolite, an organic moisture absorbent, an inorganic moisture absorbent, or other materials. A moisture-reactive adsorbent material can include metal powders such as alumina, metal oxide, metal salt, or a mixture of one or two or more of the above-mentioned materials, such as phosphorus pentoxide (P₂O₅). In addition, a physical adsorbent material can include silica, zeolite, titania, zirconia, montmorillonite, or the like. In this case, the specific examples of the metal oxide can include lithium oxide (Li₂O), sodium oxide (Na₂O), barium oxide (BaO), calcium oxide (CaO), magnesium oxide (MgO), or the like. The examples of the metal salt can include sulfates, such as lithium sulfate (Li₂SO₄), sodium sulfate (Na₂SO₄), calcium sulfate (CaSO₄), magnesium sulfate (MgSO₄), cobalt sulfate (CoSO₄), and gallium sulfate (Ga₂(SO₄)₃), titanium sulfate (Ti(SO₄)₂), or nickel sulfate (NiSO₄), metal halides, such as calcium chloride (CaCl₂), magnesium chloride (MgCl₂), strontium chloride (SrCl₂), yttrium chloride (YCl₃), magnesium bromide (MgBr₂), copper chloride (CuCl₂), cesium fluoride (CsF), tantalum fluoride (TaFs), magnesium iodide (Mgl₂), niobium fluoride (NbFs), lithium bromide (LiBr), calcium bromide (CaBr₂), cesium bromide (CeBr₃), selenium bromide (SeBr₄), or vanadium bromide (VBr₃), or metal chlorides, such as barium perchlorate (Ba(ClO₄)₂) or magnesium perchlorate (Mg(ClO₄)₂). However, the present disclosure is not limited thereto.

The first moisture absorbent material 181b can be made of a transparent material to implement the transparent first dam 181. However, the present disclosure is not limited thereto. The first dam 181 can further include the first spacer 181c.

The first spacer 181c is not limited to a particular material, but can be made of, for example, glass fiber, silicon oxide (SiO₂), rod or powder, a carbon material, or the like. The first spacer 181c can be processed to have a larger size than the first moisture absorbent material 181b and can be dispersed in the first sealant 181a. The first spacer 181c can form and maintain a preset gap between the substrate 101 and the encapsulation substrate 140 in the first dam 181. Therefore, the first spacer 181c can prevent or inhibit the first dam 181 from being collapsed by pressure which is applied when the substrate 101 and the encapsulation substrate 140 are being joined/bonded/sealed.

The first spacer 181c can be made of a transparent material to implement the transparent first dam 181. However, the present disclosure is not limited thereto.

According to an additional embodiment, the first dam 181 can further include the first getter 181d. The first getter 181d can include one or more getter materials such as solids or other materials that can collect free gases by adsorption, absorption or occlusion.

For example, the first getter 181d can include at least any one of barium oxide (BaO), calcium oxide (CaO), magnesium oxide (MgO), magnesium sulfate (MgSO₄), sodium oxide (Na₂O), sodium sulfate (Na₂SO₄), lithium sulfate (LiSO), calcium sulfate (CaSO₄), potassium oxide (K₂O), lithium oxide (Li₂O), gallium sulfate (GaS), calcium chloride (CaCl₂), magnesium chloride (MgCl₂), calcium bromide (CaBr₂), cerium bromide (CsBr), vanadium bromide (VBr₅), and calcium nitrate (Ca(No₃)₂). The first getter 181d can be configured as a particle with a size of 50 to 100 nm. For example, the first getter 181d can be physically mixed with the first sealant 181a by using a ball-mill or ultrasonic dispersion technology. However, the present disclosure is not limited thereto.

The first getter 181d can be made of a transparent material to implement the transparent first dam 181. However, the present disclosure is not limited thereto.

According to an additional example, the first dam 181 can further include the first polymer light-emitting material 181e. The first polymer light-emitting material 181e can be dissolved in a solvent and dispersed in the first sealant 181a. The first polymer light-emitting material 181e can be used as an indicator for inspecting an external appearance of the transparent first dam 181 and evaluating the reliability of the transparent first dam 181. For example, the first polymer light-emitting material 181e is transparent in a visible ray area and thus does not decrease a transmittance rate of the transparent first dam 181, and the first polymer light-emitting material 181e generates light by being irradiated with ultraviolet rays. As such, the external appearance of the first dam 181 can be inspected by emitting ultraviolet rays based on the properties of the first polymer light-emitting material 181e. In addition, the first polymer light-emitting material 181e can be degraded when exposed to moisture, which can degrade the emission properties. Therefore, the first polymer light-emitting material 181e can be used to evaluate the performance of the first dam 181, such as moisture penetration.

For example, the first polymer light-emitting material 181e can include polythiophene (PTh) and derivatives thereof, poly-p-phenylenevinylene (PPV) and derivatives thereof, poly-p-phenylene (PPP) and derivatives thereof, polyfluorene (PF) and derivatives thereof, and polyarylenevinylene (PAV) and derivatives thereof. The first polymer light-emitting material 181e can be dissolved and dispersed in a solvent, e.g., the first sealant 181a. For example, the first polymer light-emitting material 181e can be physically mixed with the first sealant 181a by using a ball-mill or ultrasonic dispersion technology. However, the present disclosure is not limited thereto.

FIG. 7 relates to the second dam 182 and schematically illustrates materials that can constitute the second dam 182.

Referring to FIG. 7, the second dam 182 can be made of transparent materials to implement a transparent display device. The transparent materials, which can constitute the second dam 182, can include a second sealant 182a and the second spacer 182c.

The transparent materials, which can constitute the second dam 182, can further include a second moisture absorbent (also referred to herein as a second moisture absorbent material or element). The transparent materials, which can constitute the second dam 182, can further include a second getter. The transparent materials, which can constitute the second dam 182, can further include a second polymer light-emitting material. According to the embodiment of the present disclosure, the second moisture absorbent, the second getter, and/or the second polymer light-emitting material can be selectively excluded.

For example, the second spacer 182c, which is a soft spacer, can be made of silicon-based polymer or acrylic copolymer. Particularly, the second spacer 182c can include acrylic copolymer. However, the present disclosure is not limited thereto. The second spacer 182c can partially include silicon-based polymer.

The first sealant 181a, which can constitute the first dam 181, and the second sealant 182a, which can constitute the second dam 182, can include or can be made up of the same material(s) or substantially the same material(s). Therefore, the boundary between the first dam 181 and the second dam 182 may not be visually recognized. The boundary between the first dam 181 and the second dam 182 may not be distinguishable even with a difference in the composition of the sealant. However, the first dam 181 and the second dam 182 can be distinguished depending on the types of spacers (e.g., the first spacer 181c and the second spacer 182c) that respectively constitute the first dam 181 and the second dam 182.

For example, a dam, which mainly includes the first spacer 181c, can be the first dam 181, and a dam, which mainly includes the second spacer 182c, can be the second dam 182. In the example of the present disclosure, the phrase “mainly includes” can be determined to be the total volume of the first spacer 181c and the total volume of the second spacer 182c or by comparing the total number of first spacers 181c and the total number of second spacers 182c.

The first spacer 181c and the second spacer 182c can be respectively applied by dispenser devices or by using a same single dispenser device. The second spacer 182c can be applied by using a dispenser device that applies the first spacer 181c. Therefore, it is possible to minimize the design and modification of the process design due to the new introduction of the second spacer 182c.

As a variation to the first dam 181 having one first spacer 181c and the second dam 182 having one second spacer 182c as shown in FIGS. 3 to 5, the first dam 181 can include a plurality of the first spacers 181c (multiple first spacers 181c) in each first area DI along the non-display area NA and/or the second dam 182 can include a plurality of the second spacers 182c (multiple second spacers 182c) in each second area D2 along the non-display area NA. For instance, given the cross-sectional view of each of FIGS. 3 to 5, multiple first spacers 181c may be present in the first area DI and/or multiple second spacers 182c may be present in the second area D2 (e.g., as shown in FIG. 7).

Accordingly, in the examples of FIGS. 1-7, the present disclosure provides a display device having two or more types of dams disposed directly adjacent to each other, which help to maintain a constant gap between an encapsulation substrate and a substrate. Further, the display device according to aspects of the present disclosure utilizes the first and second spacers having different hardnesses and/or recovery rates, so as to minimize impact on a protective layer, especially during the joining of the substrate 101 and the encapsulation substrate 140. As such, the display device with the improved configurations enhances the reliability of the display device and lengthens the lifespan of the display device.

The example embodiments of the present disclosure can also be described as follows:

According to an aspect of the present disclosure, there is provided a display device. The display device includes a substrate (e.g., base substrate) divided into a display area and a non-display area, a bonding film and an encapsulation substrate disposed over the substrate and a dam disposed in the non-display area between the substrate and the encapsulation substrate, where the dam comprises a first dam comprising a first spacer and a second dam disposed between the bonding film and the first dam and comprising a second spacer softer than the first spacer.

The display device can further comprise an organic light-emitting element disposed in the display area of the substrate and including an anode, an organic layer, and a cathode and a protective layer disposed over the organic light-emitting element.

The organic layer and the cathode can extend into the non-display area, and the cathode can be disposed to cover the organic layer in one side non-display area.

The display device can further comprise a gate pad part disposed in another side non-display area and partially disposed below the second dam, a planarization layer can extend and can be disposed over the gate pad part.

The display device can further comprise a capping layer disposed on the cathode, the capping layer can be disposed to cover the cathode in another side non-display area and still another side non-display area.

The protective layer can extend into the non-display area, and the protective layer can be disposed to cover the capping layer, the cathode, and the organic layer.

The protective layer can be disposed to extend into a lower side of the second dam in another non-display area, the protective layer can be disposed to extend into lower sides of the first and second dams in still another side non-display area, and the protective layer can be disposed to extend into the lower side of the second dam in one side non-display area.

A GIP line can be disposed toward the outside of the substrate from the gate pad part, and the GIP line can extend into a lower side of the first dam.

The display device can further comprise a first power shorting bar disposed on a side surface of the display area in one side non-display area and still another side non-display area, the planarization layer can extend to cover the first power shorting bar.

The organic layer can extend to cover the extending planarization layer in one side non-display area, and a second power shorting bar can be disposed on a side surface of the extending organic layer.

The cathode can extend to cover the second power shorting bar and the organic layer, and a part of the extending cathode can constitute a power line.

The bonding film can be disposed on the protective layer.

The bonding film can include a moisture absorbent material.

The first dam further can include a sealant and a moisture absorbent material dispersed in the sealant.

The first spacer can restrict a gap between the substrate and the encapsulation substrate, and the second spacer can restrict a gap between the encapsulation substrate and the protective layer.

The first spacer can have a circular shape, and the second spacer can have an elliptical shape.

At least one of a hardness and a restoring force of the first spacer can be higher than that of the second spacer.

The second spacer can be made of silicon-based polymer or acrylic copolymer.

The first dam and the second dam can be in contact with each other.

The first dam and the second dam can be transparent in a visible ray area.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto.

Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device comprising:
a base substrate including a display area configured to display an image and a non-display area adjacent to the display area;
a bonding film and an encapsulation substrate disposed on the base substrate; and
a dam disposed in the non-display area between the base substrate and the encapsulation substrate,
wherein the dam comprises:
a first dam comprising a first spacer; and
a second dam disposed between the bonding film and the first dam and comprising a second spacer, and
wherein the second spacer is softer than the first spacer.

2. The display device of claim 1, further comprising:
an organic light-emitting element disposed in the display area of the base substrate and including an anode, an organic layer, and a cathode; and
a protective layer disposed on the organic light-emitting element.

3. The display device of claim 2, wherein the organic layer and the cathode extend into the non-display area, and
wherein the cathode is disposed to cover the organic layer in one side portion of the non-display area.

4. The display device of claim 1, further comprising:
a gate pad part disposed in another side portion of the non-display area and partially disposed below the second dam; and
a planarization layer disposed on the gate pad part.

5. The display device of claim 4, further comprising:
a capping layer disposed on the cathode and the planarization layer in the non-display area.

6. The display device of claim 2, wherein the protective layer extends into the non-display area, and
wherein the protective layer is disposed to cover the cathode and the organic layer.

7. The display device of claim 2, wherein the protective layer is disposed to extend into a lower side of the second dam in a first side portion of the non-display area,
wherein the protective layer is disposed to extend into lower sides of the first and second dams in a second side portion of the non-display area, and
wherein the first and second side portions of the non-display area are opposite side portions.

8. The display device of claim 4, further comprising:
a gate-in-panel (GIP) line disposed on the base substrate and extending from the gate pad part,
wherein the GIP line extends from a lower side of the second dam into a lower side of the first dam in the non-display area.

9. The display device of claim 4, further comprising:
a first power shorting bar disposed at a side surface of the display area in the non-display area,
wherein the planarization layer extends to cover the first power shorting bar in the non-display area.

10. The display device of claim 9, further comprising:
an organic light-emitting element disposed in the display area of the base substrate and including an anode, an organic layer, and a cathode,
wherein the organic layer extends to cover the extending planarization layer in the non-display area; and
a second power shorting bar disposed at a side surface of the extending organic layer.

11. The display device of claim 10, wherein the cathode extends to cover the second power shorting bar and the organic layer, and
wherein a part of the extending cathode constitutes a power line.

12. The display device of claim 2, wherein the first spacer of the first dam in the non-display area maintains a gap between the base substrate and the encapsulation substrate, and
wherein the second spacer of the second dam in the non-display area maintains a gap between the encapsulation substrate and the protective layer.

13. The display device of claim 1, wherein the first spacer of the first dam in the non-display area has a circular shape, and
wherein the second spacer of the second dam in the non-display area has an elliptical shape.

14. The display device of claim 1, wherein at least one of a hardness and a restoring force of the first spacer of the first dam in the non-display area is higher than that of the second spacer of the second dam in the non-display area.

15. The display device of claim 14, wherein the second spacer of the second dam in the non-display area is made of silicon-based polymer or acrylic copolymer.

16. An organic light-emitting display device comprising:
a first substrate including a display area configured to display an image and a non-display area surrounding the display area;
a plurality of organic light-emitting elements disposed in the display area on the first substrate, wherein some layers of the plurality of organic light-emitting elements extend into the non-display area;
a second substrate covering the plurality of organic light-emitting elements and disposed opposite to the first substrate in the non-display area, wherein the first and second substrates are joined to each other; and
a first dam and a second dam disposed in the non-display area between the first and second substrates, and respectively including a first spacer and a second spacer respectively disposed inside of the first and second dams,
wherein the second spacer of the second dam in the non-display area has a more flattened circular shape than the first spacer of the first dam in the non-display area.

17. The organic light-emitting display device of claim 16, wherein the second dam is located closer to the display area than the first dam.

18. The organic light-emitting display device of claim 16, further comprising:
a protective layer covering the some layers of the plurality of organic light-emitting elements extending into the non-display area,
wherein the protective layer extends into a lower side of the second spacer of the second dam.

19. The organic light-emitting display device of claim 18, further comprising:
a gate pad part disposed in the non-display area under the protective layer, and extending into the lower side of the second spacer of the second dam.

20. The organic light-emitting display device of claim 19, further comprising:
a pixel power shorting bar disposed in the non-display area under the protective layer.

21. The organic light-emitting display device of claim 20, further comprising:
a common power shorting bar disposed in the non-display area under the protective layer,
wherein the pixel power shorting bar and the common power shorting bar are disposed adjacent to each other on the first substrate.

22. The organic light-emitting display device of claim 16, wherein at least one of a hardness and a restoring force of the first spacer of the first dam in the non-display area is higher than that of the second spacer of the second dam in the non-display area.
